(19) United States
(12) Patent Application Publication
(10) Pub. No.: US 2025/0031497 A1
(43) Pub. Date: Jan. 23, 2025

(54) DISPLAY DEVICE COMPRISING DISPLAY MODULE, AND MANUFACTURING METHOD THEREFOR

(71) Applicant: SAMSUNG ELECTRONICS CO., LTD., Suwon-si (KR)

(72) Inventors: Seonghwan SHIN, Suwon-si (KR); Gunwoo KIM, Suwon-si (KR); Tackmo LEE, Suwon-si (KR); Soonmin HONG, Suwon-si (KR)

(73) Assignee: SAMSUNG ELECTRONICS CO., LTD., Suwon-si (KR)

(21) Appl. No.: 18/906,800

(22) Filed: Oct. 4, 2024

Related U.S. Application Data
(63) Continuation of application No. PCT/KR2023/004551, filed on Apr. 5, 2023.

(30) Foreign Application Priority Data
May 31, 2022 (KR) 10-2022-0067225
Jul. 28, 2022 (KR) 10-2022-0094251

(51) Int. Cl. H01L 33/56; H01L 25/075; H01L 25/16; H01L 27/15

(52) U.S. Cl. CPC H01L 33/56; H01L 25/0753; H01L 25/167; H01L 27/156

(57) ABSTRACT

A display module includes: a substrate including a mounting surface having a thin-film transistor (TFT) layer is formed thereon, a side surface, and a rear surface opposite to the mounting surface; a plurality of inorganic light-emitting elements mounted on the mounting surface; an anisotropic conductive layer on the TFT layer and configured to electrically connect the TFT layer with the plurality of inorganic light-emitting elements; a front cover for covering the mounting surface; a side cover for surrounding the side surface; and a metal plate adhered to the rear surface. A side end of the front cover extends to a region outside the mounting surface. The side cover is made of a moisture-proof material for preventing moisture from permeating, and extends to at least a part of a side surface of the metal plate from a lower portion of the front cover corresponding to the region outside the mounting surface.

### CROSS-REFERENCE TO RELATED APPLICATIONS

This application is a continuation of International Application No. PCT/KR2023/004551, filed on Apr. 5, 2023, which is based on and claims priority to Korean Patent Application 10-2022-0067225, filed on May 31, 2022, in the Korean Intellectual Property Office, and Korean Patent Application 10-2022-0094251, filed on Jul. 28, 2022, in the Korean Intellectual Property Office, the disclosures of which are incorporated by reference herein in their entireties.

### BACKGROUND

### 1. Field

The present disclosure relates to a display apparatus, and more particularly to a display apparatus having combined modules in an inorganic light emitting device that is self-luminous and mounted on a substrate.

### 2. Description of the Related Art

A display apparatus is a type of an output device that visually displays data information such as characters and figures, and images.

In general, a display apparatus has mainly used a liquid crystal panel that requires a backlight or an organic light-emitting diode (OLED) panel provided with a film of an organic compound that emits light by itself in response to an electric current. However, the liquid crystal panel has difficulties such as a slow-response time, and high-power consumption, and further it is difficult to make the liquid crystal panel compact because the liquid crystal panel does not emit light by itself, and requires a backlight. In addition, because the OLED panel emit light by itself, the OLED panel does not require a backlight, and thus it is possible to make the OLED panel thin. However, the OLED panel is susceptible to a burn-in phenomenon when the same screen is displayed for a long time, such that a part of the screen remains even when the screen is switched due to the life of sub-pixels being ended. Accordingly, a micro light emitting diode (micro-LED or μLED) panel that mounts an inorganic light emitting element on a substrate and uses the inorganic light emitting element itself as a pixel has been studied as a new panel to replace the OLED.

A micro-light emitting diode display panel (hereinafter referred to as a micro-LED panel) is one of the flat display panels and is composed of a plurality of inorganic light emitting diodes (inorganic LEDs) that is 100 micrometers or less.

The micro-LED panel is also a self-light emitting device, but the micro-LED does not suffer from the screen burn-in and has excellent luminance, resolution, power consumption, and durability because of its inorganic nature.

In comparison with the LCD panel requiring a backlight, a micro-LED panel may offer better contrast, response times, and energy efficiency. Both organic light emitting diodes (OLEDs) and micro-LEDs corresponding to inorganic light emitting devices have good energy efficiency. However, the micro-LED has higher brightness and emission efficiency, and longer lifetime than the OLED.

In addition, by arraying the LEDs on a circuit board in pixel units, it is possible to manufacture a display module in a substrate unit, and it is easy to manufacture in various resolutions and screen sizes according to the customer's order.

### SUMMARY

Provided is a display apparatus and a manufacturing method thereof, and more particularly, a display module that may be capable of being suitable for enlargement and a display apparatus including the display module which may be capable of protecting the display module from permeation of external solutions.

Provided is a display module and a display apparatus including the display module which may be capable of protecting the display module from electrostatic discharge.

According to an aspect of the present disclosure, a display module includes: a substrate including a mounting surface having a thin-film transistor (TFT) layer formed thereon, a side surface, and a rear surface opposite to the mounting surface; a plurality of inorganic light-emitting elements mounted on the mounting surface; an anisotropic conductive layer on an upper surface of the TFT layer and configured to electrically connect the TFT layer to the plurality of inorganic light-emitting elements; a front cover covering the mounting surface; a side cover surrounding the side surface; and a metal plate bonded to the rear surface.

A side end of the front cover may extend to a region outside the mounting surface.

The side cover may be made of a moisture-proof material capable of preventing permeation of moisture, and extend to at least a portion of a side surface of the metal plate from a lower portion of the front cover corresponding to the region outside the mounting surface.

A side end of the anisotropic conductive layer may extend to the region outside the mounting surface and correspond to the side end of the front cover, and an upper surface of the side cover corresponding to the region outside the mounting surface may contact a lower surface of the anisotropic conductive layer corresponding to the region outside the mounting surface.

The display module may further include a side end cover extending from at least a portion of the side end of the front cover to at least a portion of a side end of the side cover in a direction to which the mounting surface faces, and may be configured to cover a side end of the anisotropic conductive layer.

The side end cover may have a black color.

The side end cover may be made of a moisture-proof material capable of preventing permeation of moisture.

The side end cover may extend from a front end of the front cover to an under-side of the side end of the anisotropic conductive layer in the direction to which the mounting surface faces.

The side cover may have a black color.

The side cover may be made of a water-repellent material.

The display module may further include a grounding member covering at least a portion of a side end of the side cover and contacting the side surface of the metal plate.

The grounding member may be made of a metal material.

The side cover may extend from a front end of the side end of the front cover to the side surface of the metal plate in a direction, to which the mounting surface faces.

According to another aspect of the present disclosure, a display apparatus includes: a display module array in which a plurality of display modules is horizontally arranged in an M*N matrix form; and a frame configured to support the plurality of display modules. Each of the plurality of display modules may include: a substrate including a mounting surface having a thin-film transistor (TFT) layer formed thereon, a side surface, and a rear surface opposite side to the mounting surface; a plurality of inorganic light-emitting elements mounted on the mounting surface; an anisotropic conductive layer on an upper surface of the TFT layer and configured to electrically connect the TFT layer to the plurality of inorganic light-emitting elements; a front cover covering the mounting surface; a side cover surrounding the side surface; and a metal plate bonded to the rear surface.

A side end of the front cover may extend to a region outside the mounting surface.

The side cover may be made of a moisture-proof material capable of preventing permeation of moisture, and may extend to at least a portion of a side surface of the metal plate from a lower portion of the front cover corresponding to the region outside the mounting surface.

A side end of the anisotropic conductive layer may extend to the region outside the mounting surface and correspond to the side end of the front cover, and an upper surface of the side cover corresponding to the region outside the mounting surface may contact a lower surface of the anisotropic conductive layer corresponding to the region outside the mounting surface.

The display apparatus may further include a side end cover extending from at least a portion of the side end of the front cover to at least a portion of a side end of the side cover in a direction to which the mounting surface faces, and covering a side end of the anisotropic conductive layer.

The side end cover may have a black color.

The side end cover may be made of a moisture-proof material capable of preventing permeation of moisture.

The side end cover may extend from a front end of the front cover to an under-side of the side end of the anisotropic conductive layer in the direction to which the mounting surface faces.

The side cover may have a black color.

The side end cover may be made of a water-repellent material.

The display apparatus may further include a grounding member covering at least a portion of a side end of the side cover and contacting a side surface of the metal plate.

A display module of a display apparatus may include a front side and a lateral side sealed by a front cover and a side cover which may improve reliability from permeation of external solutions.

Further, a display module of a display apparatus may improve electrostatic discharge (ESD) withstand voltage from ESD, which may be generated in the display module, by a side end cover provided to cover a side end of an anisotropic conductive layer.

### BRIEF DESCRIPTION OF THE DRAWINGS

Additional aspects will be set forth in part in the description which follows and, in part, will be apparent from the description, or may be learned by practice of the presented embodiments.

FIG. 1 is a view illustrating a display apparatus according to some embodiments of the disclosure.

FIG. 2 is an exploded-view illustrating main components of the display apparatus of FIG. 1.

FIG. 3 is an enlarged cross-sectional view illustrating some components of one display module shown in FIG. 1.

FIG. 4 is a rear perspective view illustrating the display module of the display apparatus shown in FIG. 1.

FIG. 5 is a perspective view illustrating some components of the display module shown in FIG. 1.

FIG. 6 is a cross-sectional view illustrating a part of the configuration of the display apparatus of FIG. 1 with respect to a third direction.

FIG. 7 is an enlarged cross-sectional view illustrating some components shown in FIG. 6.

FIG. 8 is an enlarged cross-sectional view illustrating some components of a display apparatus according to some embodiments of the present disclosure.

FIG. 9 is an enlarged cross-sectional view illustrating some components of a display apparatus according to some embodiments of the present disclosure.

FIG. 10 is an enlarged cross-sectional view illustrating some components of a display apparatus according to some embodiments of the present disclosure.

FIG. 11 is an enlarged cross-sectional view illustrating some components of a display apparatus according to some embodiments of the present disclosure.

### DETAILED DESCRIPTION

Embodiments described in the disclosure and configurations shown in the drawings are merely examples of the embodiments of the disclosure, and the scope of the disclosure should be understood to include various modifications or equivalents to replace the embodiments at the time of filing of the present application.

The singular forms “a,” “an” and “the” are intended to include the plural forms as well, unless the context clearly indicates otherwise. The shapes and sizes of elements in the drawings may be exaggerated for the clear description.

In describing the drawings, similar reference numerals may be used to designate similar constituent elements.

A singular expression may include a plural expression unless otherwise indicated herein or clearly contradicted by context.

The expressions “A or B,” “at least one of A or/and B,” or “one or more of A or/and B,” A, B or C,” “at least one of A, B or/and C,” or “one or more of A, B or/and C,” and the like used herein may include any and all combinations of one or more of the associated listed items.

The term of “and/or” includes a plurality of combinations of relevant items or any one item among a plurality of relevant items.

Herein, the expressions “a first”, “a second”, “the first”, “the second”, etc., may simply be used to distinguish an element from other elements, but is not limited to another aspect (importance or order) of elements.

When an element (e.g., a first element) is referred to as being “(functionally or communicatively) coupled,” or “connected” to another element (e.g., a second element), the first element may be connected to the second element, directly (e.g., wired), wirelessly, or through a third element.

In this disclosure, the terms “including”, “having”, and the like are used to specify features, numbers, steps, operations, elements, components, or combinations thereof, but do not preclude the presence or addition of one or more of the features, elements, steps, operations, elements, components, or combinations thereof.

When an element is said to be “connected”, “coupled”, “supported” or “contacted” with another element, this includes not only when elements are directly connected, coupled, supported or contacted, but also when elements are indirectly connected, coupled, supported or contacted through a third element.

Throughout the description, when an element is “on” another element, this includes not only when the element is in contact with the other element, but also when there is another element between the two elements.

In this disclosure, the meaning of “identical” may include things being similar in properties to each other or are similar within a certain range. In addition, the meaning “identical” refers to “substantially identical”. It should be understood that the meaning of “substantially identical” refers to a value that falls within an error range in manufacturing or a value having a difference within a range that does not have significance with respect to a reference value.

Hereinafter embodiments according to the disclosure will be described in detail with reference to the accompanying drawings.

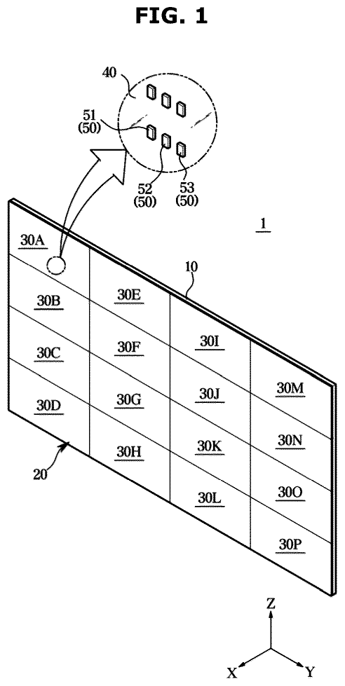

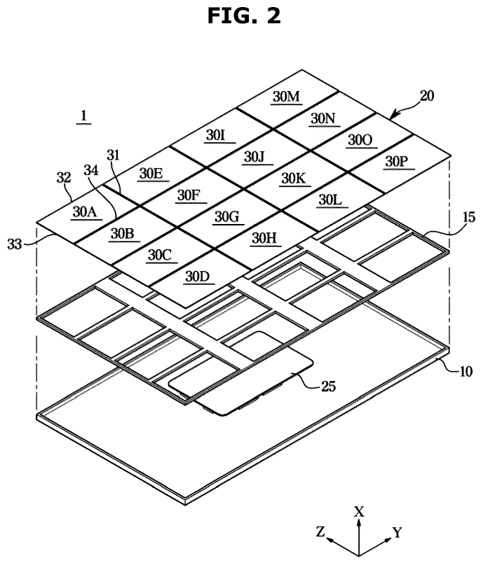

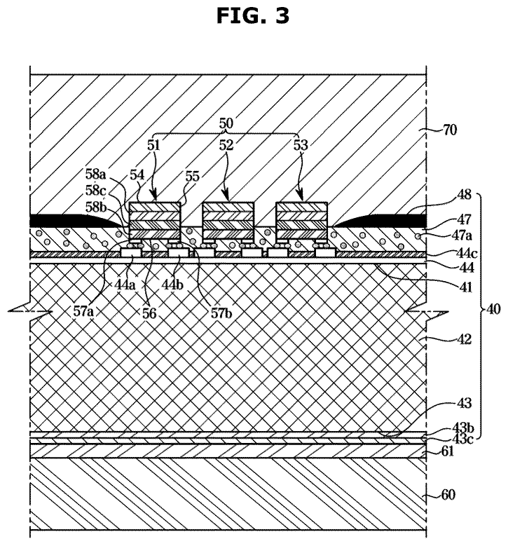

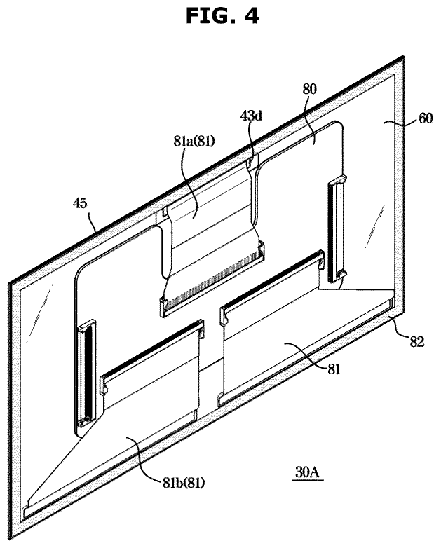

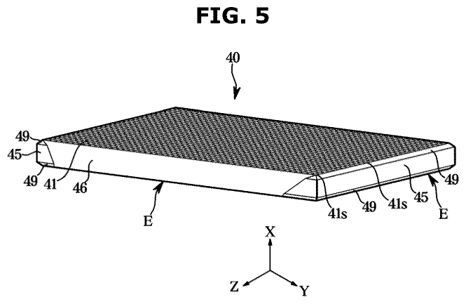

FIG. 1 is a view illustrating a display apparatus according to some embodiments of the disclosure, FIG. 2 is an exploded-view illustrating main components of the display apparatus of FIG. 1, FIG. 3 is an enlarged cross-sectional view illustrating some components of one display module shown in FIG. 1, FIG. 4 is a rear perspective view illustrating the display module of the display apparatus shown in FIG. 1, and FIG. 5 is a perspective view illustrating some components of the display module shown in FIG. 1.

Components of a display apparatus 1 including a plurality of inorganic light emitting elements 50 illustrated in the drawings are components in a micro-unit having a size of several μm to hundreds of μm, and for convenience of description, the size of some components (the plurality of inorganic light emitting elements 50 and a black matrix 48, etc.) are exaggerated.

The display apparatus 1 is a device that displays information, material, data, etc. as characters, figures, graphs, images, etc. and a television, a personal computer, mobile, and a digital signage may be implemented as the display apparatus 1.

According to some embodiments of the disclosure, as shown in FIGS. 1 and 2, the display apparatus 1 may include a display panel 20 provided to display an image, a power supply device configured to supply power to the display panel 20, a main board 25 configured to control an overall operation of the display panel 20, a frame 15 provided to support the display panel 20, and a rear cover 10 provided to cover a rear surface of the frame 15.

The display panel 20 may include a plurality of display modules 30A to 30P, a driver board configured to drive each of the display modules 30A to 30P, and a timing controller (T-con) board configured to generate a timing signal to control the each of the display modules 30A to 30P.

The rear cover 10 may support the display panel 20. The rear cover 10 may be installed on the floor through a stand, or may be installed on a wall through a hanger.

The plurality of display modules 30A to 30P may be arranged vertically and horizontally to be adjacent to each other. The plurality of display modules 30A to 30P may be arranged in an M*N matrix. In the embodiment, 16 display modules 30A to 30P are provided and arranged in a matrix of 4*4, but there is no limitation in the number and arrangement method of the plurality of display modules 30A to 30P.

The plurality of display modules 30A to 30P may be installed in the frame 15. The plurality of display modules 30A to 30P may be installed in the frame 15 through various known methods such as magnetic force using a magnet or a mechanical fitting structure. The rear cover 10 may be coupled to the rear of the frame 15, and the rear cover 10 may form a rear appearance of the display apparatus 1.

The rear cover 10 may include a metal material. Accordingly, heat generated from the plurality of display modules 30A to 30P and the frame 15 may be easily conducted to the rear cover 10 to increase the heat dissipation efficiency of the display apparatus 1.

As described above, the display apparatus 1 according to the embodiment of the present disclosure may implement a large screen by tiling the plurality of display modules 30A to 30P.

In other embodiments of the disclosure, the plurality of display modules 30A to 30P may be individually applied to a display apparatus. That is, the display modules 30A to 30P may be singly installed and applied to a wearable device, a portable device, a handheld device and an electronic product or an electronic component that requires a display. As described in the embodiment of the present disclosure, the plurality of display modules 30A to 30P may be applied to a display apparatus such as a monitor for a personal computer (PC), a high-resolution TV and a signage, an electronic display, in a matrix form through assembly.

The plurality of display modules 30A to 30P may include the same configuration. Accordingly, a description of any one display module described below may be equally applied to all other display modules.

Hereinafter each of the plurality of display modules 30A to 30P will be described with reference to a first display module 30A because the plurality of display modules 30A to 30P has the same configuration.

That is, in order to avoid redundant descriptions, a display module 30, a substrate 40, and a front cover 70 will be described as representative of the configuration of the plurality of display modules 30A to 30P.

In addition, the first display module 30A, a third display module 30E arranged adjacent to the first display module 30A in a second direction Y, or a second display module 30B arranged adjacent to the first display module 30A in a third direction Z among the plurality of display modules 30A to 30P will be described if necessary.

Among the plurality of display modules 30A to 30P, the first display module 30A may be formed in a quadrangle type. Alternatively, the first display module 30A may be provided in a rectangle type or a square type.

Accordingly, the first display module 30A may include edges 31, 32, 33, and 34 formed in up, down, left and right directions with respect to a first direction X, which is the front.

As illustrated in FIG. 3, each of the plurality of display modules 30A to 30P may include the substrate 40 and a plurality of inorganic light emitting elements 50 mounted on the substrate 40. The plurality of inorganic light emitting elements 50 may be mounted on a mounting surface 41 of the substrate 40 facing the first direction X. In FIG. 3, for convenience of description, a thickness of the substrate 40 in the first direction X is shown to be enlarged.

The substrate 40 may be formed in a quadrangle type. As described above, the each of the plurality of display modules 30A to 30P may be provided in a quadrangle type, and thus the substrate 40 may be formed in a quadrangle type to correspond to the type of the display module.

Alternatively, the substrate 40 may be provided in a rectangle type or a square type.

Therefore, as for the first display module 30A, the substrate 40 may include 4 edges E corresponding to the edges 31, 32, 33, and 34 of the first display module 30A formed in four directions of up, down, left and right with respect to the first direction X that is the front (refer to FIG. 5).

The first display module 30A may include a right edge 31, an upper edge 32, a left edge 33 and a lower edge 34 with respect to the first direction X that is the front side on which a screen of the display module 30A is displayed. The right edge 31 and the left edge 33 may be arranged to face each other in the second direction Y that is the left and right direction, and the upper edge 32 and the lower edge 34 may be arranged to face each other in the third direction Z that is the vertical direction.

The substrate 40 may include a substrate body 42, the mounting surface 41 forming one surface of the substrate body 42, a rear surface 43 arranged opposite to the mounting surface 41 and forming the other surface of the substrate body 42, and a side surface 45 arranged between the mounting surface 41 and the rear surface 43.

The side surface 45 may form a side end of the substrate 40 in the second direction Y and the third direction Z that are perpendicular to the first direction X.

The substrate 40 may include a chamfer 49 formed between the mounting surface 41 and the side surface 45 and between the rear surface 43 and the side surface 45.

The chamfer 49 may prevent the respective substrates from being collided and damaged when the plurality of display modules 30A to 30P is arranged.

The edge E of the substrate 40 is a concept including the side surface 45 and the chamfer 49.

The substrate 40 may include a thin film transistor (TFT) layer 44 formed on the substrate body 42 to drive the inorganic light emitting element 50. The substrate body 42 may include a glass substrate. That is, the substrate 40 may include a Chip on Glass (COG) type substrate. First and second pad electrodes 44a and 44b provided to electrically connect the inorganic light emitting element 50 to the TFT layer 44 may be formed on the substrate 40.

A thin film transistor (TFT) forming the TFT layer 44 is not limited to a specific structure or type, and may be configured in various embodiments. That is, the TFT of the TFT layer 44 according to some embodiments of the present disclosure may be implemented as an organic TFT and a graphene TFT as well as a Low Temperature Poly Silicon (LTPS) TFT, an oxide TFT, and a Si TFT such as a poly silicon, or a-silicon TFT.

Alternatively, when the substrate body 42 of the substrate 40 is formed of a silicon wafer, the TFT layer 44 may be replaced with a Complementary Metal-Oxide Semiconductor (CMOS) transistor, or n-type MOSFET or p-type MOSFET transistor.

The plurality of inorganic light emitting elements 50 may be formed of an inorganic material, and may include inorganic light emitting elements having sizes of several μm to several tens of μm in width, length, and height, respectively. The micro-inorganic light emitting device may have a length of 100 μm or less on a short side among width, length, and height. That is, the inorganic light emitting element 50 may be picked up from a sapphire or silicon wafer and directly transferred onto the substrate 40. The plurality of inorganic light emitting elements 50 may be picked up and transported through an electrostatic method using an electrostatic head or a stamp method using an elastic polymer material such as PDMS or silicon, as a head.

The plurality of inorganic light emitting elements 50 may be a light emitting structure including an n-type semiconductor 58a, an active layer 58c, a p-type semiconductor 58b, a first contact electrode 57a, and a second contact electrode 57b.

Although not shown in the drawing, one of the first contact electrodes 57a and the second contact electrode 57b may be electrically connected to the n-type semiconductor 58a and the other of the first contact electrodes 57a and the second contact electrode 57b may be electrically connected to the p-type semiconductor 58b.

The first contact electrode 57a and the second contact electrode 57b may be a flip chip type as to be disposed in parallel with each other while facing in the same direction (a direction opposite to an emission direction).

The inorganic light emitting element 50 may include a light emitting surface 54 arranged to face the first direction X when mounted on the mounting surface 41, a side surface 55, and a bottom surface 56 arranged opposite to the light emitting surface 54. The first contact electrode 57a and the second contact electrode 57b may be formed on the bottom surface 56.

That is, the contact electrodes 57a and 57b of the inorganic light emitting element 50 may be arranged on the opposite side of the light emitting surface 54, and accordingly, the contact electrodes 57a and 57b may be arranged on the opposite side to the direction in which light is emitted.

The contact electrodes 57a and 57b may be arranged to face the mounting surface 41, and provided to be electrically connected to the TFT layer 44. The light emitting surface 54 emitting light may be arranged in a direction opposite to the direction in which the contact electrodes 57a and 57b are arranged.

Therefore, when light generated from the active layer 58c is emitted in the first direction X through the light emitting surface 54, the light may be emitted toward the first direction X without the interference of the first contact electrode 57a or the second contact electrode 57b.

That is, the first direction X may be defined as a direction in which the light emitting surface 54 is arranged to emit light.

The first contact electrode 57a and the second contact electrode 57b may be electrically connected to a first pad electrode 44a and a second pad electrode 44b, respectively, formed on the mounting surface 41 of the substrate 40.

The inorganic light emitting element 50 may be directly connected to the pad electrodes 44a and 44b through an anisotropic conductive layer 47 or a bonding structure such as solder.

The anisotropic conductive layer 47 may be formed on the substrate 40 to mediate electrical bonding between the contact electrodes 57a and 57b and the pad electrodes 44a and 44b. The anisotropic conductive layer 47 may include a structure in which an anisotropic conductive adhesive is attached on a protective film, and particularly, a structure in which conductive balls 47a are scattered in an adhesive resin. The conductive ball 47a may be a conductive sphere surrounded by a thin insulating film, and may electrically connect a conductor and a conductor to each other as the insulating film is broken by a pressure.

The anisotropic conductive layer 47 may include an anisotropic conductive film (ACF) in the form of a film and an anisotropic conductive paste (ACP) in the form of a paste.

In some embodiments according to the present disclosure, the anisotropic conductive layer 47 may be provided with an anisotropic conductive film.

Therefore, by a pressure applied to the anisotropic conductive layer 47 when the plurality of inorganic light emitting elements 50 is mounted on the substrate 40, the insulating film of the conductive balls 47a may be broken and thus the contact electrodes 57a and 57b of the inorganic light emitting element 50 may be electrically connected to the pad electrodes 44a and 44b of the substrate 40.

The plurality of inorganic light emitting elements 50 may be mounted on the substrate 40 through solder instead of the anisotropic conductive layer 47. After the inorganic light emitting element 50 is aligned on the substrate 40, the inorganic light emitting element 50 may be bonded to the substrate 40 through a reflow process.

The plurality of inorganic light emitting elements 50 may include a red light emitting device 51, a green light emitting device 52, and a blue light emitting device 53. As for the inorganic light emitting element 50, a series of the red light emitting device 51, the green light emitting device 52, and the blue light emitting device 53 may be mounted on the mounting surface 41 of the substrate 40 as one unit. A series of the red light emitting device 51, the green light emitting device 52, and the blue light emitting device 53 may form a single pixel. In this case, the red light emitting device 51, the green light emitting device 52, and the blue light emitting device 53 may form a sub-pixel, respectively.

The red light emitting device 51, the green light emitting device 52, and the blue light emitting device 53 may be arranged in a line at a predetermined interval according to the embodiment of the present disclosure, and alternatively, arranged in other shapes such as a triangular shape.

The substrate 40 may include a light absorbing layer 44c to absorb external light to improve the contrast. The light absorbing layer 44c may be formed on the entire mounting surface 41 of the substrate 40. The light absorbing layer 44c may be formed between the TFT layer 44 and the anisotropic conductive layer 47.

The plurality of display modules 30A to 30P may further include a black matrix 48 formed between the plurality of inorganic light emitting elements 50.

The black matrix 48 may perform a function of supplementing the light absorbing layer 44c formed entirely on the mounting surface 41 of the substrate 40. That is, the black matrix 48 may absorb external light to allow the substrate 40 to appear black, thereby improving the contrast of the screen.

The black matrix 48 may have a black color.

According to some embodiments, the black matrix 48 may be arranged between pixels formed by a series of the red light emitting device 51, the green light emitting device 52, and the blue light emitting device 53. The black matrix 48 may be formed at a higher precision to partition each of the light emitting devices 51, 52, and 53, which are the sub-pixels.

The black matrix 48 may be formed in a grid shape having a horizontal pattern and a vertical pattern to be arranged between pixels.

The black matrix 48 may be formed by applying a light-absorbing ink on the anisotropic conductive layer 47 and then curing the light-absorbing ink through an ink-jet process, or by coating the anisotropic conductive layer 47 with a light-absorbing film.

That is, on the anisotropic conductive layer 47 formed entirely on the mounting surface 41, the black matrix 48 may be arranged on a space, in which the plurality of inorganic light emitting elements 50 is not mounted, between the plurality of inorganic light emitting elements 50.

The plurality of display modules 30A to 30P may include a front cover 70 arranged in the first direction X on the mounting surface 41 to cover the mounting surface 41 of the plurality of display modules 30A to 30P.

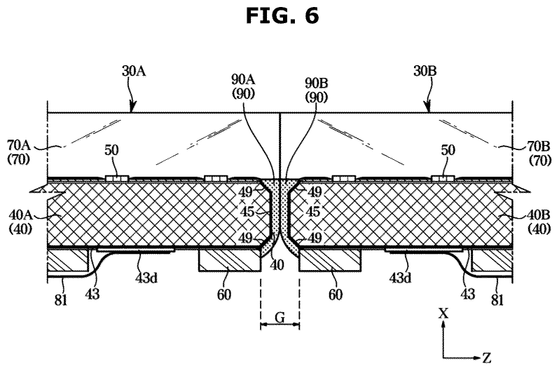

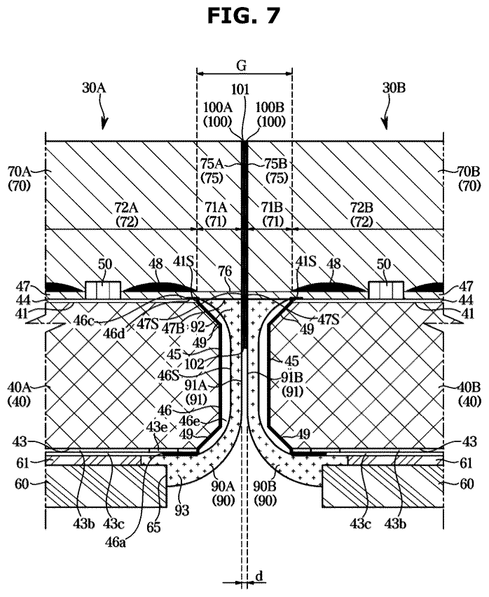

The front cover 70 may be provided in plurality so as to be respectively formed in the first direction X on the plurality of display modules 30A to 30P (refer to FIGS. 6 and 7).

Each of the plurality of display modules 30A to 30P may be assembled after each front cover 70 thereof is formed. That is, as for the first display module 30A and the second display module 30B among the plurality of display modules 30A to 30P, a first front cover 70A may be formed on a mounting surface 41 of the first display module 30A and a second front cover 70B may be formed on a mounting surface 41 of the second display module 30B.

The front cover 70 may be provided to cover the substrate 40 to protect the substrate 40 from external force or external moisture.

A plurality of layers of the front cover 70 may be provided as a functional film having optical performance. This will be described later in detail.

A part of the plurality of layers of the first cover 70 may include a base layer formed of optical clear resin (OCR). The base layer may be provided to support a plurality of other layers. The OCR may be in a highly transparent state having a transmittance of 90% or more.

The OCR may improve visibility and image quality by increasing transmittance through low reflection properties. That is, in a structure including an air gap, light loss may occur due to a difference in refractive index between the film layer and the air layer. However, in a structure including the OCR, the difference in refractive index may be reduced and thus light-loss may also be reduced, thereby improving the visibility and image quality.

That is, the OCR may improve image quality as well as protecting the substrate 40.

A part of the plurality of layers may include an adhesive layer provided to bond the front cover 70 to the mounting surface 41 of the substrate 40.

In general, the front cover 70 may be provided to include a predetermined height or more in the first direction X to which the mounting surface 41 or the light emitting surface 54 faces.

This is to sufficiently fill a gap that may be formed between the front cover 70 and the plurality of inorganic light emitting elements 50 when the front cover 70 is formed on the substrate 40.

Each of the plurality of display modules 30A to 30P may include a metal plate 60 arranged on the rear surface 43 of the substrate 40.

Further, each of the plurality of display modules 30A to 30P may include a rear adhesive tape 61 arranged between the rear surface 43 and the metal plate 60 to bone the metal plate 60 to the rear surface 43 of the substrate 40.

The rear adhesive tape 61 may be provided as a double-sided adhesive tape, but is not limited thereto, and may be provided in the form of an adhesive layer instead of a tape shape. That is, the rear adhesive tape 61 is an example of a medium for bonding the metal plate 60 to the rear surface 43 of the substrate 40, and is not limited to the tape and may be provided in various medium shapes.

The plurality of inorganic light emitting elements 50 may be electrically connected to a pixel driving wiring formed on the mounting surface 41, and a front wiring layer extending through the side surface 45 of the substrate 40 and formed as a pixel driving wiring.

The front wiring layer may be formed under the anisotropic conductive layer 47. The front wiring layer may be electrically connected to a side wiring 46 formed on the side surface 45 of the substrate 40. The side wiring 46 may be provided in the form of a thin film. The side wiring 46 may include a coating member 46b surrounding the side wiring 46 to prevent damage that may occur when the side wiring 46 is exposed to the outside (refer to FIG. 7).

The side wiring 46 may extend to the rear surface 43 of the substrate 40 along the chamfer 49 and the side surface 45 of the substrate 40 in the third direction Z, along the third direction Z. That is, the side wiring 46 may extend to the rear surface 43 of the substrate 40 along the chamfer 49 and the side surface 45 of the substrate 40 on the upper edge 32 and the lower edge 34.

However, the present disclosure is not limited thereto and the side wiring 46 may extend to the rear surface 43 of the substrate 40 along the chamfer 49 and the side surface 45 of the substrate 40 in the second direction Y, along the second direction Y, not the third direction Z.

Further, the present disclosure is not limited thereto and the side wiring 46 may extend along one edge E of the substrate 40 corresponding to at least two edges among the four edges 31, 32, 33 and 34 of the first display module 30A. The front wiring layer may be connected to the side wiring 46 through a front pad formed on the edge E of the mounting surface 41.

The side wiring 46 may extend along the side surface 45 of the substrate 40 and may be connected to a rear wiring layer 43b formed on the rear surface 43. Particularly, the side wiring 46 may be connected to a rear pad 43e to which the rear wiring layer 43c and the side wiring 46 are electrically connected. The rear pad 43e may be formed on the edge E of the rear surface 43 of the substrate 40.

An insulating layer 43c covering the rear wiring layer 43b may be formed on the rear wiring layer 43b in a direction to which the rear surface of the substrate 40 faces.

That is, the plurality of inorganic light emitting elements 50 may be sequentially and electrically connected to the front wiring layer, the side wiring 46, and the rear wiring layer 43b.

Further, as shown in FIG. 4, the display module 30A may include a driver circuit board 80 configured to electrically control the plurality of inorganic light emitting elements 50 mounted on the mounting surface 41. The driver circuit board 80 may be formed of a printed circuit board. The driver circuit board 80 may be arranged on the rear surface 43 of the substrate 40 in the first direction X. The driver circuit board 80 may be arranged on the metal plate 60 bonded to the rear surface 43 of the substrate 40.

The display module 30A may include a flexible film 81 connecting the driver circuit board 80 to the rear wiring layer 43b to allow the driver circuit board 80 to be electrically connected to the plurality of inorganic light emitting elements 50.

Particularly, one end of the flexible film 81 may be connected to a connection pad 43d arranged on the rear surface 43 of the substrate 40 and electrically connected to the plurality of inorganic light emitting elements 50.

The connection pad 43d may be electrically connected to the rear wiring layer 43b. Accordingly, the connection pad 43d may electrically connect the rear wiring layer 43b to the flexible film 81.

Because the flexible film 81 is electrically connected to the connection pad 43d, the flexible film 81 may transmit power and an electrical signal from the driver circuit board 80 to the plurality of inorganic light emitting elements 50.

The flexible film 81 may be formed of a flexible flat cable (FFC) or a chip on film (COF).

The flexible film 81 may include a first flexible film 81a and a second flexible film 81b that are respectively arranged in the vertical direction with respect to the first direction X that is the front.

The first and second flexible films 81a and 81b are not limited thereto, and may be arranged in the left and right directions with respect to the first direction X, or may be arranged in at least two directions in the up, down, left, and right directions, respectively.

The second flexible films 81b may be provided in plurality. However, the present disclosure is not limited thereto, and a single second flexible film 81b may be provided, and the first flexible films 81a may also be provided in plurality.

The first flexible film 81a may transmit a data signal from the driver circuit board 80 to the substrate 40. The first flexible film 81a may be formed of COF.

The second flexible film 81b may transmit power from the driver circuit board 80 to the substrate 40. The second flexible film 81b may be formed of FFC.

However, the present disclosure is not limited thereto, and the first flexible film 81a and the second flexible film 81b may be formed opposite to each other.

The driver circuit board 80 may be electrically connected to a main board 25 (refer to FIG. 2). The main board 25 may be arranged on the rear side of the frame 15, and at the rear of the frame 15, the main board 25 may be connected to the driver circuit board 80 through a cable.

A fixing member 82 provided to allow the display modules 30A to 30P to be attached to the frame 15 may be arranged on the rear surface of the metal plate 60. It is appropriate that the fixing member 82 is provided with a double-sided tape. The metal plate 60 forming the rear of the display module 30A to 30P may be directly attached to the frame 15 by the fixing member 82, and thus the display modules 30A to 30P may be supported by the frame 15.

As described above, the metal plate 60 may be provided to be in contact with the substrate 40. The metal plate 60 and the substrate 40 may be bonded to each other by the rear adhesive tape 61 arranged between the rear surface 43 of the substrate 40 and the metal plate 60.

FIG. 5 illustrates the substrate 40 without components such as the anisotropic conductive layer 47 for convenience of description. Further, the side wiring 46 includes the coating member 46e provided to protect the side wiring 46 from the outside. However, the coating member 46e is omitted in the drawings for convenience of description.

The metal plate 60 may be formed of a metal material having high thermal conductivity. For example, the metal plate 60 may be formed of an aluminum material.

Heat generated by the plurality of inorganic light emitting elements 50 and the TFT layer 44 mounted to the substrate 40 may be transferred to the metal plate 60 through the rear adhesive tape 61 along the rear surface 43 of the substrate 40.

Accordingly, heat generated by the substrate 40 may be easily transferred to the metal plate 60 and it is possible to prevent the substrate 40 from rising above a predetermined temperature.

The plurality of display modules 30A to 30P may be arranged in various positions in the form of an M*N matrix. Each of the display modules 30A to 30P is provided to be individually movable. In this case, each of the display modules 30A to 30P may include the metal plate 60 to maintain a constant level of heat dissipation performance regardless of the position where each of the display modules 30A to 30P is arranged.

The plurality of display modules 30A to 30P may be provided in the form of various M*N matrixes so as to form various-sized screen of the display apparatus 1. Accordingly, in comparison with heat dissipation using a single metal plate provided for heat dissipation, each of the display modules 30A to 30P may include an independent metal plate 60 so as to individually dissipate the heat according to some embodiments of the disclosure, thereby improving the heat dissipation performance of the entire display apparatus 1.

When a single metal plate is arranged inside the display apparatus 1, a part of the metal plate may not be arranged at a position corresponding to a position where some display modules are arranged with respect to the front and rear direction, and the metal plate may be arranged at a position corresponding to a position where any display module is not arranged with respect to the front and rear direction. Therefore, the heat dissipation efficiency of the display apparatus 1 may be reduced.

That is, because a respective one of the metal plate 60 is disposed on each of the display modules 30A to 30P, each of the display modules 30A to 30P may individually perform self-heat dissipation by the respective one of the metal plate 60 regardless of the position where each of the display modules 30A to 30P is disposed, and thus it is possible to improve the total heat dissipation performance of the entire display modules 30A to 30P.

The metal plate 60 may be provided in a quadrangular shape substantially corresponding to the shape of the substrate 40.

An area of the substrate 40 may be at least equal to or greater than an area of the metal plate 60. When the substrate 40 and the metal plate 60 are arranged side by side in the first direction X, the four edges of the substrate 40 having a rectangular shape may be formed to correspond to the four edges of the metal plate 60 with respect to the center of the substrate 40 and the metal plate 60, or the four edges of the substrate 40 having a rectangular shape may be formed to be arranged on the outer side than the four edges of the metal plate 60 with respect to the center of the substrate 40 and the metal plate 60.

It is appropriate that the four edges E of the substrate 40 is provided to be arranged outside the four edges of the metal plate 60. That is, the area of the substrate 40 may be provided to be greater than the area of the metal plate 60.

The substrate 40 and the metal plate 60 may thermally expand by heat transferred to each of the display modules 30A to 30P. Because the metal plate 60 has a higher coefficient of thermal expansion than the substrate 40, the metal plate 60 may expand by a scale greater than a scale by which the substrate 40 expands.

In this case, the edge of the metal plate 60 may protrude to a region outside the substrate 40 when the four edges E of the substrate 40 are disposed to correspond to the four edges of the metal plate 60 or are disposed to correspond to a region inside the four edges of the metal plate 60.

Accordingly, a separation distance of a gap formed between the respective display modules 30A to 30P may be irregularly formed by the thermal expansion of the metal plate 60 of each of the modules 30A to 30P. Therefore, the visibility of a seam may be increased, and the sense of unity of the screen of the display panel 20 may be lowered.

However, even when the substrate 40 and the metal plate 60 thermally expand, the metal plate 60 may not protrude to the outside of the four edges E of the substrate 40 because the four edges E of the substrate 40 is arranged outside the four edges of the metal plate 60. Accordingly, the separation distance of the gap formed between the display modules 30A to 30P may be kept constant.

According to some embodiments of the present disclosure, the substrate 40 and the metal plate 60 may be provided to have areas approximately corresponding to each other. Accordingly, heat generated from the substrate 40 may be uniformly radiated over the entire region of the substrate 40 without being isolated to a partial region.

The metal plate 60 may be bonded to the rear surface 43 of the substrate 40 by the rear adhesive tape 61.

The rear adhesive tape 61 may have a size corresponding to that of the metal plate 60. That is, the area of the rear adhesive tape 61 may be provided to correspond to the area of the metal plate 60. The metal plate 60 may be provided in a substantially quadrangular shape, and the rear adhesive tape 61 may be provided in a quadrangular shape to correspond to the shape of the metal plate 60.

The edge of the metal plate 60 and the edge of the rear adhesive tape 61 in the rectangular shape may be formed to correspond to each other with respect to the center of the metal plate 60 and the rear adhesive tape 61.

Accordingly, the metal plate 60 and the rear adhesive tape 61 may be easily manufactured in a single coupling configuration, and thus the manufacturing efficiency of the display apparatus 1 may be increased as a whole.

That is, when the metal plate 60 is cut in units of preset number from one plate, the adhesive layer 61 may be bonded to the one plate in advance before the metal plate 60 is cut, and the rear adhesive layer 61 and the metal plate 60 may be simultaneously cut in units of preset number, thereby reducing the number of processes.

Heat generated by the substrate 40 may be transferred to the metal plate 60 through the rear adhesive tape 61. Accordingly, the rear adhesive tape 61 may be provided to bond the metal plate 60 to the substrate 40 while transferring the heat generated by the substrate 40 to the metal plate 60.

Accordingly, the rear adhesive tape 61 may include a material having high heat dissipation performance.

The rear adhesive tape 61 may include a material having an adhesive property to bond the substrate 40 and the metal plate 60.

Additionally, the rear adhesive tape 61 may include a material having higher heat dissipation performance than a material having general adhesive properties. Accordingly, heat may be efficiently transferred between the substrate 40 and the metal plate 60 to each component.

In addition, the adhesive material of the rear adhesive layer 61 may be formed of a material having a heat dissipation performance higher than that of an adhesive material forming a general adhesive.

A material having higher heat dissipation performance means a material that effectively transfers heat with high thermal conductivity, high heat transfer, and low specific heat.

For example, the rear adhesive tape 61 may include a graphite material. However, the present disclosure is not limited thereto, and the rear adhesive tape 61 may be generally formed of a material having high heat dissipation performance.

Ductility of the rear adhesive tape 61 may be greater than that of the substrate 40 and that of the metal plate 60. Accordingly, the rear adhesive tape 61 may be formed of a material having high ductility while having adhesive properties and heat dissipation properties. The rear adhesive tape 61 may be formed of an inorganic double-sided tape. As described above, the rear adhesive tape 61 is formed of an inorganic tape, and thus the rear adhesive tape 61 may be provided as a single layer without a base material supporting one surface bonded to the substrate 40 and the other surface bonded to the metal plate 60, between the one surface and the other surface.

Because the rear adhesive tape 61 does not include a base material, the rear adhesive tape 61 may not include a material that interferes with heat dissipation, thereby increasing the heat dissipation performance. However, the rear adhesive tape 61 is not limited to the inorganic double-sided tape, and may be provided as a heat-dissipating tape having better heat dissipation performance than a general double-sided tape.

The rear adhesive tape 61 may be formed of a material with high ductility so as to absorb the external force transmitted from the substrate 40 and the metal plate 60. Particularly, the ductility of the rear adhesive tape 61 may be greater than that of the substrate 40 and the metal plate 60.

Accordingly, when the external force, which is generated by the size change of the substrate 40 and the metal plate 60 due to the heat transmitted to the substrate 40 and the metal plate 60, is transmitted to the rear adhesive tape 61, the rear adhesive tape 61 may be deformed itself and thus the rear adhesive tape 61 may prevent the external force from being transmitted to different components.

The rear adhesive tape 61 may have a predetermined thickness in the first direction X. When the metal plate 60 is subject to heat and thermally expanded or cooled and contracted, the metal plate 60 may be expanded or contracted in a direction perpendicular to the first direction X as well as the first direction X, and thus an external force may be transmitted to the substrate 40.

As described above, the metal plate 60 is formed to have a size corresponding to that of the substrate 40 and is provided to cover the entire rear surface 43 of the substrate 40, and thus the fixing member 82 may be arranged on the rear surface of the metal plate 60.

However, the present disclosure is not limited thereto, and the fixing member 82 may be provided to be arranged on the rear surface 43 of the substrate 40. In this case, the substrate 40 may be directly bonded to the frame 15 through the fixing member 82.

The metal plate 60 may be provided to cover a portion of the rear surface 43 of the substrate 40, and on the rear surface 43 of the substrate 40, the fixing member 82 may be bonded to a region that is not covered by the metal plate 60.

It is appropriate that the fixing member 82 is provided with a double-sided tape.

Hereinafter the front cover 70, a side cover 90, and a side end cover 100 will be described in detail.

FIG. 6 is a cross-sectional view illustrating some components of the display apparatus of FIG. 1 with respect to a third direction, and FIG. 7 is an enlarged cross-sectional view illustrating some components shown in FIG. 6.

The term “vertical direction” used in the following description refers to the first direction X, which is the direction, to which the mounting surface 41 faces, based on the cross-sectional view of the display apparatus of FIG. 6. The first direction X may be arranged in the front and rear direction to allow the screen of the display apparatus to face a user when the display apparatus is installed. Hereinafter the first direction X may correspond to the vertical direction.

The front cover 70 may protect the substrate 40 from the external force, and may reduce the visibility of the seam formed by a gap G formed between the plurality of display modules 30A to 30P, and may reduce color deviation between the plurality of display modules 30A to 30P.

The plurality of display modules 30A to 30P may include the side cover 90 arranged in the gap G formed between the plurality of display modules 30A to 30P in response to the array of the plurality of display modules 30A to 30P.

The front cover 70 of the plurality of display modules 30A to 30P may extend to the outside of the substrate 40 of the plurality of display modules 30A to 30P so as to adsorb light reflected from the gap G between the plurality of display modules 30A to 30P. A side end 75 of the front cover 70 may extend to a region outside the mounting surface 41.

Particularly, the front cover 70 may be provided to extend to the outer side than an edge (or side end) 41S of the mounting surface 41 of the substrate 40 in the second direction Y and the third direction Z.

Substantially, the gap between the respective display modules 30A to 30P may be generated between the side surfaces 45 of the substrate 40 of the respective display modules 30A to 30P. However, according to some embodiments of the present disclosure, the gap may mean a non-display region generated between the respective display modules 30A to 30P, and thus the gap G formed between the plurality of display modules 30A to 30P should be understood as separation from one of the side end 41S of the mounting surface 41 of the substrate 40 of one of the display modules 30A to 30P to another one of the side end 41S of the mounting surface 41 of the substrate 40 of another one of the display modules 30A to 30P adjacent thereto.

Therefore, the gap G formed between the plurality of display modules 30A to 30P may refer to separation formed between one of the side end 41S of the mounting surface 41 of the substrate 40 of one of the display modules 30A to 30P to another one of the side end 41S of the mounting surface 41 of the substrate 40 of another one of the display modules 30A to 30P adjacent thereto in the second direction Y or the third direction Z.

The front cover 70 extending from each of the display modules 30A to 30P may be arranged in the gap G between the plurality of display modules 30A to 30P, and thus the front cover 70 may absorb light emitted to the gap G or light reflected from the gap G, thereby minimizing the perception of the seam.

In addition, as will be described later, the light emitted to the gap G may be absorbed by the side cover 90 of the plurality of display modules 30A to 30P arranged between the gap G, thereby minimizing the perception of the seam.

As illustrated in FIGS. 6 and 7, the front cover 70 may be provided to extend to the outside of the substrate 40 in the third direction Z. Particularly, the front cover 70 may be provided to extend to a region outside the side surface 45 and the chamfer 49 in the third direction Z.

For example, only one edge of the substrate 40 corresponding to the lower edge 34 of the first display module 30A has been described, but the front cover 70 may extend to regions outside the four edges E of the substrate 40 in the second direction Y or the third direction Z.

That is, the side end 75 of the front cover 70 corresponding to the edge of the front cover 70 may extend to regions outside the four edges E of the substrate 40, which is outside the mounting surface 41, in the second direction Y or the third direction Z.

The front cover 70 may include a plurality of layers each having different optical properties. Each of the plurality of layers may be provided in a structure laminated in the first direction X. Each of the plurality of layers may be bonded to each other in the first direction Z, thereby forming the front cover 70.

Among the plurality of layers, one layer may be provided as an anti-glare layer. For example, one layer may be provided as an anti-reflective layer or a layer in which an anti-glare layer and an anti-reflective layer are mixed.

Among the plurality of layers, other layer may be provided as a light transmittance control layer. For example, other layer may be formed of a layer including different physical properties or materials or having different functions. For example, other layer may be provided as a circular polarization layer.

For example, the plurality of layers may be provided as a single layer. A single layer may be provided as a layer configured to functionally implement all the functions of the plurality of layers.

For example, the front cover 70 may include an adhesive layer. The adhesive layer may be arranged at a rearmost side of the plurality of layers in the first direction X and bonded to the mounting surface 41. The adhesive layer may be provided to have a predetermined height in the first direction X to which the mounting surface 41 or the light emitting surface 54 faces.

When the adhesive layer is bonded to the substrate 40, a gap that may be formed between the adhesive layer and the plurality of inorganic light emitting elements 50 may be sufficiently filled with the predetermined height of the adhesive layer.

For example, the adhesive layer may be provided as a component, which is separated from the front cover 70 and arranged between the front cover 70 and the mounting surface 41, thereby bonding the front cover 70 to the mounting surface 41.

Accordingly, the front cover 70 may be closely bonded to the mounting surface 41 so as to protect components mounted on the mounting surface 41 and thus the display module 30 may directly bond the front cover 70 to the substrate 40 without an additional molding structure between the front cover 70 and the substrate 40.

The front cover 70 may be provided to diffusely reflect the light incident from the outside so as to prevent the externally incident light from being regularly reflected and dazzling the user.

As light incident from the outside is diffusely reflected, a glare phenomenon may be reduced and the contrast of a screen displayed on the display panel 20 may be improved.

Further, the front cover 70 may be provided to reduce the transmittance of incident external light or the transmittance of external light reflected from the substrate 40 and the gap G.

The front cover 70 may include a material that reduces the transmittance of light, and absorb at least a portion of light transmitted toward the substrate 40 or at least a portion of light reflected from the substrate 40 and to face the first direction X.

When a plurality of substrates is produced, some substrates may have different colors due to process errors during the production. Accordingly, substrates having different unique colors may be tiled to form a single display panel.

As described above, the front cover 70 according to some embodiments of the present disclosure may absorb at least a portion of the light that is reflected from the substrate 40 and transmitted to the outside, thereby increasing the sense of unity of the screen of the display panel 20.

That is, the front cover 70 may reduce the color deviation of each display module 30A to 30P, which is generated in the production process of the plurality of display modules 30A to 30P, by lowering the external light transmittance.

The front cover 70 may prevent external light, which is incident from the outside to the display panel 20, from being transmitted to the substrate 40, and additionally absorb a portion of light incident on the display panel 20 from the outside or a portion of light that is reflected from the substrate 40 and transmitted to the outside of the display panel 20. Therefore, the front cover 70 may improve the contrast of the screen displayed on the display panel 20. The different optical actions may be respectively implemented using the above-described plurality of layers.

That is, the front cover 70 may be arranged in front of the substrate 40 with respect to the first direction X to improve the contrast that may be reduced by external light on the screen displayed on the display panel 20.

As described above, in the display module 30 according to some embodiments of the present disclosure, the front cover 70 may be provided to extend to a region outside the substrate 40 in the third direction Z.

Accordingly, a portion of the light introduced into the gap G formed between the plurality of display modules 30A to 30P may be blocked by at least a portion of the front cover 70 arranged in the gap G, and at least a portion of external light introduced into the gap G or external light reflected from the gap G may be absorbed by the front cover 70, and thus the light may be not transmitted to the outside. Therefore, it is possible to reduce the visibility of the seam formed in the gap G, and thus it is possible to increase the sense of unity of the screen displayed on the display panel 20 as the visibility of the seam is reduced.

Particularly, the side end 75 of the front cover 70 in the third direction Z may be arranged in a region outside the side end 41S of the mounting surface 41 in the third direction Z or in the gap G.

Accordingly, the front cover 70 may include a first region 71 arranged in a region outside the side end 41S of the mounting surface 41 in the third direction Z or in the gap G, and a second region 72 arranged on the mounting surface 41.

The first region 71 and the second region 72 of the front cover 70 may be partitioned with respect to the third direction Z by the gap G.

The first region 71 of the front cover 70 may be arranged in the gap G and thus external light emitted to the gap G may be blocked by the first region 71 of the front cover 70 and light reflected from the gap G may be prevented from being emitted to the outside. Therefore, it is possible to reduce the visibility of the seam, which is a boundary between the plurality of display modules 30A to 30P and generated by the gap G, and thus it is possible to improve the sense of unity of the display panel 20.

The front cover 70 may be provided to extend to a region outside the four edges 41S of the mounting surface 41 of the substrate 40 as described above, and thus the visibility of the seam, which is formed at each edge of the plurality of display modules 30A to 30P, may be reduced.

When the first display module 30A and the second display module 30B are described as an example, a first region 71A of the first front cover 70A extending from the first display module 30A may be arranged in the gap G formed between the first display module 30A and the second display module 30B.

A side end 75A of the front cover 70A of the first display module 30A and a side end 75B of a front cover 70B of the second display module 30B adjacent to the first display module 30A in the second display module 30B may be disposed in the gap G.

Further, the side surface 45 and the chamfer 49 of the first and second display modules 30A and 30B may be arranged in the gap G.

A second region 72A of the front cover 70A of the first display module 30A may be arranged on the mounting surface 41 of the first display module 30A.

A first region 71B of the front cover 70B of the second display module 30B extending from the second display module 30B may be arranged in the gap G formed between the first display module 30A and the second display module 30B. A second region 72B of the front cover 70B of the second display module 30B may be arranged on the mounting surface 41 of the second display module 30B.

That is, in the gap G formed between the first display module 30A and the second display module 30B, the first region 71A of the first cover 70A of the first display module 30A and the first region 71B of the front cover 70B of the second display module 30B may be arranged side by side in the third direction Z.

A length in which the first region 71A of the first cover 70A of the first display module 30A extends in the third direction Z and a length in which the first region 71B of the front cover 70B of the second display module 30B extends in the third direction Z may be approximately less than or equal to half of the gap G.

Accordingly, the sum of the length of the first region 71A of the first cover 70A of the first display module 30A and the length of the first region 71B of the front cover 70B of the second display module 30B may be provided to be approximately less than or equal to the length of the gap G.

As described above, in the gap G between the first display module 30A and the second display module 30B, the first region 71A of the front cover 70A of the first display module 30A and the first region 71B of the front cover 70B of the second display module 30B may be arranged.

While external light incident on the display panel 20 passes through the first region 71A of the front cover 70A of the first display module 30A and the first region 71B of the front cover 70B of the second display module 30B, the external light may be diffusely reflected to the outside of the display panel 20 or partially absorbed to the first region 71A of the front cover 70A of the first display module 30A and the first region 71B of the front cover 70B of the second display module 30B. Accordingly, an amount of light reaching the gap G may be reduced, and the revelation of the boundary between the first display module 30A and the second display module 30B due to the gap G may be reduced.

In addition, while light, which is reflected from the gap G and directed to the outside of the display panel 20, passes through the first region 71A of the front cover 70A of the first display module 30A and the first region 71B of the front cover 70B of the second display module 30B, the light may be diffusely reflected to the outside of the display panel 20 or partially absorbed to the first region 71A of the front cover 70A of the first display module 30A and the first region 71B of the front cover 70B of the second display module 30B. Accordingly, an amount of light that is transmitted to the outside of the display panel 20 may be reduced, and the revelation of the boundary between the first display module 30A and the second display module 30B due to the gap G may be reduced.

That is, it is possible to absorb at least a portion of external light reflected from the gap G while reducing the amount of light introduced into the gap P formed between the plurality of display modules 30A to 30P. Accordingly, it is possible to improve the sense of unity of the screen of the display panel 20.

Additionally, even when a substrate 40A of the first display module 30A and a substrate 40B of the second display module 30B have different colors, at least a portion of light, which is reflected when each of the substrate 40A of the first display module 30A and the substrate 40B of the second display module 30B is displayed to the outside by the reflection of the external light, may be absorbed to the front cover 70A of the first display module 30A and the front cover 70B of the second display module 30B, and thus the unique color of each of the substrate 40A of the first display module 30A and the substrate 40B of the second display module 30B may be not perceived to the outside. Therefore, it is possible to improve the sense of unity of the screen of the display panel 20.

The display module 30A may include the side cover 90 arranged under the front cover 70 with respect to a direction, to which the mounting surface 41 faces, and disposed on the side surface 45 of the substrate 40.

For example, the side end 47S of the anisotropic conductive layer 47 of the display module 30 may be disposed on the same line as the side end 75 of the front cover 70 with respect to the first direction X.

The anisotropic conductive layer 47 may be provided in the shape of an anisotropic conductive film. The anisotropic conductive layer 47 may be provided to be in the form of a film on the TFT 44 and bonded to the TFT 44. The anisotropic conductive layer 47 may be formed in a film shape, and thus an area of the anisotropic conductive layer 47 may be greater than an area of the substrate 40.

For example, after the anisotropic conductive layer 47 is bonded to the TFT layer 44, the front cover 70 may cover the mounting surface 41 of the substrate 40 and then a process of cutting the anisotropic conductive layer 47 together with the front cover 70 may be performed. During the cutting process, the anisotropic conductive layer 47 may be cut together with the front cover 70 to allow the side end 47S of the anisotropic conductive layer 47 and the side end 75 of the front cover 70 to be arranged on the same line in the first direction X through the laser cutting.

The side cover 90 may be disposed in a space formed by a lower surface 47B of the anisotropic conductive layer 47 in the first direction X and by the side surface of the substrate 40 in the third direction Z.

The side cover 90 may be provided to extend from the lower surface 47B of the anisotropic conductive layer 47 to a side surface 65 of the metal plate 60 in the first direction X.

One end portion 92 of the side cover 90 in the first direction X may be provided in contact with the lower surface 47B of the anisotropic conductive layer 47, and the other end portion 93 of the side cover 90 in the first direction X may be provided in contact with the side surface 65 of the metal plate 60.

As the side cover 90 extends from the one end portion 92 to the other end portion 93, the side cover 90 may surround not only the side surface 45 but also the entire chamfer 49 formed between the mounting surface 41 and the side surface 45.

As the side cover 90 is provided to surround the chamfer 49 formed between the mounting surface 41 and the side surface 45 and the chamfer 49 formed between the side surface 45 and the rear surface 43, the side cover 90 may cover all of the space generated between a lower surface 76 of the front cover 70 and the metal plate 60.

The side cover 90 may prevent foreign substances or moisture from entering a space between the substrate 40, the front cover 70, and the anisotropic conductive layer 47 from the outside.

The side cover 90 may prevent foreign substances or moisture from entering a space between the substrate 40 and the metal plate 60 from the outside.

The side wiring 46 may include a first end 46a connected to the rear pad 43e, a second end 46c connected to the front pad, a first end portion 46b corresponding to a region including the first end 46a and provided to be adjacent to the first end 46a in the side wiring 46, and a second end portion 46d corresponding to a region including the second end 46c and provided to be adjacent to the second end 46c in the side wiring 46.

The one end portion 92 of the side cover 90 in the first direction X may be provided to be in contact with the lower surface 76 of the front cover 70 or the lower surface 47B of the anisotropic conductive layer 47, and the other end portion 93 of the side cover 90 in the first direction X may be provided to cover at least a portion of the metal plate 60 in the first direction X. Accordingly, the side cover 90 may seal entire of the side surface 45 and the side wiring 46 so as to prevent liquids such as moisture from entering from the outside.

For example, the side end 47S of the anisotropic conductive layer 47 of the display module 30 may be disposed in a region inside the side end 75 of the front cover 75 in the third direction Z.

For example, after the anisotropic conductive layer 47 is bonded to the TFT layer 44, a process of cutting the anisotropic conductive layer 47 may be performed to allow the area of the anisotropic conductive layer 47 to correspond to the area of the substrate 40. In the cutting process, the anisotropic conductive layer 47 may be cut to allow the area of the anisotropic conductive layer 47 to correspond to the area of the substrate 40 through the laser cutting.

For example, in order to prevent damage to the substrate 40 that may occur during the cutting process, a location in which the anisotropic conductive film is cut may be a region outside the side surface 45 or a region outside a side end 46S of the side wiring 46. The side end 47S of the anisotropic conductive layer 47 may be formed in a region outside the substrate 40.

For example, the side cover 90 may be disposed in a spaced formed by the lower surface 76 of the first region 71 of the front cover 70 and the lower surface 47B of the anisotropic conductive layer 47 in the first direction X and by the side surface of the substrate 40 in the third direction Z. The lower surface 76 of the first region 71 may correspond to at least a portion of the entire lower surface of the front cover 70 and refer to a rear surface of the adhesive layer formed at a rearmost end of the front cover 70.

The side surface 45 of the substrate 40 may be provided to correspond to the four edges 41S of the mounting surface 41, and the first region 71 of the front cover 70 may extend to regions outside the four edges 41S of the mounting surface 41 in the second direction Y and in the third direction Z in which the mounting surface 41 extends.

For example, the side cover 90 may be provided to surround the lower portion of the first region 71 in the first direction X and the side surface 45 corresponding to the four edges 41S of the mounting surface 41 along the circumference of the four edges 41S of the mounting surface 41. The side cover 90 may be provided to seal the entire edge of the portion in which the substrate 40 and the front cover 70 are bonded to each other.

The side cover 90 may cover the lower surface 76 of the first region 71 and the side surface 45 in all directions perpendicular to the first direction X. Accordingly, the coupling between the front cover 70 and the substrate 40 may be improved, and the side cover 90 may protect the front cover 70 and the side surface 45 of the substrate 40 from external forces.

For example, the side cover 90 may be provided to surround a lower portion of the first region 71 in the first direction X in some of the four edges 41S of the mounting surface 41, and the side surface 45 corresponding to the some of the four edges 41S of the mounting surface 41. The side cover 90 may be provided to seal a portion of an edge of a region in which the substrate 40 and the front cover 70 are bonded. In order to protect the side wiring 46, the side cover 90 may be provided to cover only a side surface 45 in which the side wiring 46 extends, among four side surfaces 45.

For example, the side cover 90 may be disposed only on the side surface 45 corresponding to the upper edge 32 and the lower edge 34 in which the side wiring 46 extends. In order to protect the side wiring 46 and electrical components connected to the side wiring 46, which are vulnerable to damage when foreign substances enter from the outside or electrostatic discharge (ESD) occurs, the side cover 90 may be provided to cover only the side surface 45, in which the side wiring 46 extends, among four side surfaces 45.

Due to ESD that may occur on the display modules 30A to 30P, the electric current may flow into the plurality of electrical components mounted on the substrate 40 and thus the electrical components may be damaged. However, in order to prevent damage to the electrical components, the side cover 90 may seal the substrate 40 from the outside to preventing the electric charges generated by ESD from flowing into the substrate 40.

That is, the substrate 40 is sealed by the front cover 70 and the side cover 90 and thus the electric charges generated by ESD do not pass through the front cover 70 and the side cover 90. Accordingly, it is possible to prevent the electric charges from passing through the substrate 40 and to guide the electric charges, which flows on the front cover 70 and the side cover 90, to the metal plate 60 in contact with the side cover 90, thereby providing a path of the electric current generated by ESD. Accordingly, ESD withstand voltage of the electrical components mounted on the substrate 40 may be improved.

As described above, the display module 30A may be provided to be arranged under the front cover 70 with respect to a direction to which the mounting surface 41 faces.

The one end portion 92 of the side cover 90 in the first direction X may be provided under the lower surface 76 of the first region 71. This is to prevent the side cover 90 from arranging on a movement path of the light emitted from the plurality of inorganic light emitting elements 50.

The side end 75 of the front cover 70 in the third direction Z and a side end portion 91 of the side cover 90 in the third direction Z may be arranged on substantially the same line in the first direction X.

For example, the front cover 70 and the side cover 90 may be simultaneously cut in the manufacturing process of the display module 30A. Accordingly, separation formed between the plurality of display modules 30A to 30P in response to the array of the plurality of display modules 30A to 30P may be minimized, and the seam perceived through the separation between the plurality of display modules 30A to 30P may be minimized.

The side cover 90 may include a material that absorbs light. For example, the side cover 90 may be formed of an opaque or translucent material. For example, the side cover 90 may be formed of a material having a black color. The side cover 90 may be provided to have a darker color than the front cover 70. For example, the side cover 90 may be provided to have a color similar to the black matrix 48. Accordingly, the light incident on the side cover 90 may be not reflected but absorbed by the material, which absorbs the light, of the side cover 90.

For example, the side cover 90 may include a photosensitive material. For example, the side cover 90 may be formed of a photosensitive optical clear resin (OCR). When external light having a wavelength other than that of visible light, such as ultraviolet (UV) light, is emitted, physical properties of the photosensitive material may be changed, and a color of the photosensitive material may be changed to a dark color. The side cover 90 may be formed of a material that is colored to a dark color so as to absorb light when the UV light is emitted to the side cover 90 during the manufacturing process.

The side cover 90 may be formed of a moisture-proof material that prevents permeation of solutions such as moisture.

As described above, as the side cover 90 is provided to seal the edges of the display modules 30A to 30P, the side cover 90 may cover all of the side wiring 46, the first end portion 46b of the side wiring 46, the side surface 45, and the rear pad 43e connected to the side wiring 46 so as to prevent solutions such as moisture from permeating from the outside.

For example, the side cover 90 and a moisture-proof member 200 may be formed of a water-repellent material. Solutions such as moisture may flow on the side cover 90 without permeating into the side cover 90.

For example, the side cover 90 may be replaced with a water-proof material to prevent the solution from being absorbed into the side cover 90 and flowing to the side wiring 46, the rear pad 43e, or the side surface 45.

As described above, even when the side wiring 46 is exposed to the outside, some external solution may be prevented from flowing into the side wiring 46 by the coating member 46e surrounding the side wiring 46. However, when an external solution has an alkaline base, such as a cleaning solution, the coating member 46e may be removed by the alkaline solution and the side wiring 46 may be damaged. The side cover 90 may cover the entire side wiring 46 to prevent damage to the side wiring 46.

The moisture-proof member 200 may be formed at the lower end portion 92 of the side cover 90. Additionally, the moisture-proof member 200 may be provided so as not to be disposed at the side end 91 of the side cover 90.

Together with the first region 71 of the front cover 70, the side cover 90 may be arranged in the gap G formed between the plurality of display modules 30A to 30P when the plurality of display modules 30A to 30P is arrayed.

Accordingly, it is possible to absorb the light introduced into the gap G so as to minimize light that is introduced into the gap G and reflected toward the outside. Accordingly, it is possible to reduce the visibility of the seam formed by the gap G formed between the plurality of display modules 30A to 30P.

When the first display module 30A and the second display module 30B are described as an example, a side cover 90A of the first display module 30A and a side cover 90B of the second display module 30E, together with the first region 71A of the first cover 70A of the first display module 30A and the first region 71B of the front cover 70B of the second display module 30B may be arranged in the gap G formed between the first display module 30A and the second display module 30B.

A side end 91A of the side cover 90A of the first display module 30A and a side end 91B of the side cover 90B of the second display module 30B adjacent to the side end 91A of the side cover 90A of the first display module 30A may be arranged in the gap G.

The side end 91A of the side cover 90A of the first display module 30A and the side end 91B of the side cover 90B of the second display module 30B adjacent to the side end 91A of the side cover 90A of the first display module 30A may be arranged to face each other.

The side end 75A of the front cover 70A of the first display module 30A and the side end 75B of the front cover 70B of the second display module 30B adjacent to the side end 75A of the front cover 70A of the first display module 30A may be arranged to face each other.

The side end 91A of the side cover 90A of the first display module 30A and the side end 91B of the side cover 90B of the second display module 30B adjacent to the side end 91A of the side cover 90A of the first display module 30A, and the side end 75A of the front cover 70A of the first display module 30A and the side end 75B of the front cover 70B of the second display module 30B adjacent to the side end 75A of the front cover 70A of the first display module 30A may be arranged in parallel to each other.

In the gap G formed between the first display module 30A and the second display module 30B, the first region 71A of the front cover 70A of the first display module 30A and the first region 71B of the front cover 70B of the second display module 30B, and the side cover 90A of the first display module 30A and the side cover 90B of the second display module 30B may be arranged side by side in the third direction Z.

A length of the side cover 90A of the first display module 30A and the side cover 90B of the second display module 30B extending in the third direction Z in the gap G formed between the first display module 30A and the second display module 30B may be provided in approximately less than or equal to half of the gap G in accordance with the length of the first region 71A of the front cover 70A of the first display module 30A and the first region 71B of the front cover 70B of the second display module 30B.

In the gap G formed between the first display module 30A and the second display module 30B, the first region 71A of the front cover 70A of the first display module 30A and the first region 71B of the front cover 70B of the second display module 30B may be arranged, and the side cover 90A of the first display module 30A and the side cover 90B of the second display module 30B may be arranged behind each of the first region 71A of the front cover 70A of the first display module 30A and the first region 71B of the front cover 70B of the second display module 30B with respect to the first direction X.

As described above, the external light incident on the display panel 20 may be diffusely reflected to the outside of the display panel 20 or partially absorbed while passing through the first region 71A of the front cover 70A of the first display module 30A and the first region 71B of the front cover 70B of the second display module 30B. Accordingly, the amount of light reaching the gap G may be reduced.

Further, even when a portion of light reaches the gap G, the light introduced into the gap G may be absorbed by the side cover 90A of the first display module 30A and the side cover 90B of the second display module 30B, which are arranged in the gap G, and thus the revelation of the boundary between the first display module 30A and the second display module 30B may be reduced.

That is, it is possible to additionally absorb the light reaching the gap G while reducing the amount of external light introduced into the gap G formed between the plurality of display modules 30A to 30P. Accordingly, it is possible to improve the sense of unity of the screen of the display panel 20.

Further, light, which is not absorbed by the side cover 90A of the first display module 30A and the side cover 90B of the second display module 30B and is reflected on the side cover 90A of the first display module 30A and the side cover 90B of the second display module 30B and directed to the outside of the display panel 20, may be diffusely reflected to the outside of the display panel 20 or partially absorbed in the first region 71A of the front cover 70A of the first display module 30A and the first region 71B of the front cover 70B of the second display module 30B while passing through the first region 71A of the front cover 70A of the first display module 30A and the first region 71B of the front cover 70B of the second display module 30B. Accordingly, an amount of light transmitted to the outside of the display panel 20 may be reduced and the revelation of the boundary between the first display module 30A and the second display module 30B due to the gap G may be reduced.

For example, the front cover 70 may be provided to reduce the amount of light reaching the substrate 40 by diffusely reflecting, absorbing, circularly polarizing, or changing the reflection direction of a portion of the light introduced into the display module 20.

For example, the front cover 70 may be formed of a transparent material through which light is transmitted without deformation. Even in this case, the revelation of the boundary between the plurality of display modules 30A to 30P due to the gap G may be reduced by the side cover 90 arranged between the plurality of display modules 30A to 30P.

The front cover 70 may be formed of a non-conductive material through which electric charges do not pass.

The side cover 90 may be formed of a non-conductive material through which electric charges do not pass.

The front cover 70 and the side cover 90 may be formed of a non-conductive material, and thus most of the electric current applied to the front cover 70 or the side cover 90 may flow on the front cover 70 and the side cover 90 without passing through the front cover 70 and the side cover 90.

The metal plate 60 may be formed of a material having a large capacitance to serve as a ground configuration. Accordingly, when an electric current is applied to the metal plate 60, the metal plate 60 may be maintained at a constant potential and thus the electric current flowing into the metal plate 60 may be absorbed by the metal plate 60, and the electric current may not flow to the substrate 40 through the metal plate 60.

Further, all of the side wiring 46 of the substrate 40 may be covered by the side cover 90, and thus the side wiring 46 may be sealed not be exposed to the outside. Therefore, even when ESD occurs on the side surface 45 of the substrate 40, the side cover 90 may prevent the electric current from flowing into the side wiring 46.

For example, the side end 47S of the anisotropic conductive layer 47 may be disposed between the side end 91 of the side cover 90 and the side end 75 of the front cover 70, and thus a portion of the anisotropic conductive layer 47 may be exposed to the outside. For example, a defect may occur during the manufacturing process of the display module 30 and thus separation may be formed between the anisotropic conductive layer 47 and the front cover 70 or the substrate 40. During the application and curing process of the side cover 90, separation may be formed from the anisotropic conductive layer 47.

At this time, due to ESD, an electric current may flow into the inside of the display modules 30A to 30P through the anisotropic conductive layer 47 that is located adjacent to the electrical components and has low hardness and low resistance to electricity. Accordingly, the electric current may flow into the electrical components, such as the side wiring, causing damage to the components.

Each of the display modules 30A to 30P may independently include the front cover 70 and the side cover 90 provided with a non-conductive material and provided to seal the substrate 40, so as to prevent an electric current, which is generated by ESD, from flowing into a configuration mounted to the substrate 40. The front cover 70 and the side cover 90 may be provided to allow the electric current, which is generated by ESD, to be easily guided to the metal plate 60 corresponding to the ground configuration.

However, an electric current may flow into the anisotropic conductive layer 47 disposed between the front cover 70 and the side cover 90, and thus the display apparatus 1 may include a side end cover 100 provided to cover the anisotropic conductive layer 47 from the outside so as to prevent the introduction of the electric current.

One end portion 101 of the side end cover 100 in the first direction X may extend downward from a front end of the front cover 70 in the first direction X. The other end portion 102 of the side end cover 100 may extend from the one end portion 101 to at least a portion of the side cover 90 through the anisotropic conductive layer 47 in the first direction X. The side end cover 100 may be provided to extend from the side end 75 of the front cover 70 to the side end 91 of the side cover 90.

The side end cover 100 may be arranged to be disposed at a lateral-most end of the display modules 30A to 30P based on the display surface of the display modules 30A to 30P. The display surface of the display modules 30A to 30P may correspond to the screen on which the image is displayed by the plurality of inorganic light-emitting elements 50 in the display modules 30A to 30P, and a lateral-most end of the display surface may be defined as the side end 75 of the front cover 70.

The side end cover 100 may cover the side end 47S of the anisotropic conductive layer 47 to prevent the side end 47S of the anisotropic conductive layer 47 from being exposed to the outside.

For example, the side end cover 100 may be formed of a non-conductive material.

For example, the side end cover 100 may be formed through a process of coating the side end 75 of the front cover 70, the side end 47S of the anisotropic conductive layer 47, and at least a portion of the side end 91 of the side cover 90 with the side end cover 100.

Because the side end 47S of the anisotropic conductive layer 47 is not exposed to the outside by the side end cover 100, an electric current due to ESD may not flow into the anisotropic conductive layer 47 and pass through the side cover 90 along the side end cover 100, thereby being guided to the metal plate 60.

For example, the side end cover 100 may be disposed at the lateral-most end of the first display module 30A and the second display module 30B, respectively. A side end cover 100A of the first display module 30A and a side end cover 100B of the second display module 30B may be arranged side by side. The side end cover 100A of the first display module 30A and the side end cover 100B of the second display module 30B may be disposed in contact with each other.

Accordingly, a distance d between the lateral-most end of the first display module 30A and the lateral-most end of the second display module 30B may be the same as a thickness of the side end cover 100A of the first display module 30A and the side end cover 100B of the second display module 30B.

When the side end cover 100 is not provided, a grounding member that is grounded to the metal plate 60 may be additionally installed at the lateral-most end of the display modules 30A to 30P to prevent an electric current due to ESD from flowing into the anisotropic conductive layer 47. The grounding member may be generally formed of a metal material, and have a predetermined thickness or more. The grounding member may increase separation between the lateral-most ends of the display modules 30A to 30P, and accordingly, the visibility of the seam between the display modules 30A to 30P may be increased.

However, as ESD immunity due to ESD is improved by the side end cover 100 even without the grounding member, the grounding member may be not disposed at the lateral-most end of the display modules 30A to 30P. Accordingly, the distance d between the lateral-most end of the display modules 30A to 30P may be minimized, thereby reducing the visibility of the seam.

The side end cover 100 may be formed of a material having a black color. As the side end cover 100 is disposed in the gap G between the display modules 30A to 30P, the side end cover 100 may absorb the light emitted into the gap G between the display modules 30A to 30P, thereby reducing the visibility of the seam between the display modules 30A to 30P.

The side end cover 100 may be provided to cover the side end 75 of the front cover 70. In addition, as described above, the side end cover 100 is provided to have a black color, and thus it is possible to prevent light leakage phenomenon in which a portion of the light emitted by the plurality of inorganic light emitting elements 50 is transmitted through the side end 75 of the front cover 70.

For example, the side end cover 100 may be formed of a moisture-proof material. The side end cover 100 may prevent solutions such as moisture from flowing into the side end 47S of the anisotropic conductive layer 47 and the side end 75 of the front cover 70, or between the side end 47S of the anisotropic conductive layer 47 and the side end 91 of the side cover 90.

Hereinafter a display apparatus 1 without the side end cover 100 and including the grounding member 110 according to some embodiments will be described.

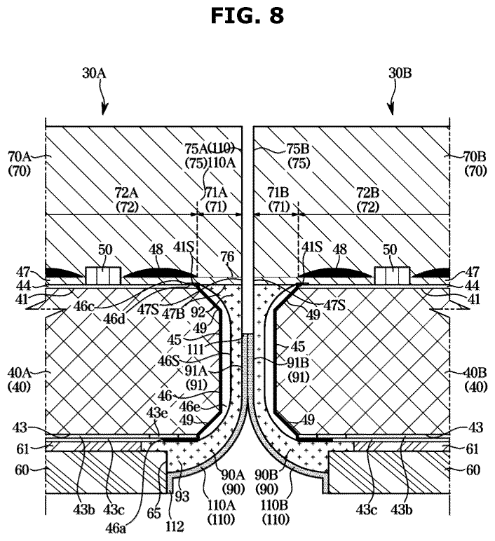

FIG. 8 is an enlarged cross-sectional view illustrating some components of a display apparatus according to some embodiments of the present disclosure.

The display apparatus 1 may include a grounding member 110 additionally disposed on the outer end of the side cover 90 in the third direction Z of the display module 30 and provided to be grounded to the metal plate 60 so as to prevent an electric current, which is generated by ESD, from moving to the side wiring 46.

The grounding member 110 may be formed of a material with higher conductivity than the side cover 90.

One end portion 111 of the grounding member 110 in the first direction X may be disposed on any portion of the side end 91 of the side cover 90, and the other end portion 112 of the grounding member 110 may be provided to be in contact with the side surface 65 of the metal plate 60.

The grounding member 110 may be provided to easily guide static electricity to the metal plate 60 even when the sealing of the display modules 30A to 30P is not perfect due to manufacturing defects.

As described above, because the anisotropic conductive layer 47 has a low resistance compared to other components, it is easy for an electric current due to ESD to flow into the anisotropic conductive layer 47. However, the grounding member may guide the electric current to the metal plate 60 so as to prevent the electric current from moving into the anisotropic conductive layer 47.

The grounding member 110 may be formed of a metal material and may be formed of a material with higher conductivity than the side cover 90. The grounding member 110 may be coated on the side cover 90 and disposed on the side end portion 91 of the side member 90.

Accordingly, when the display modules 30A to 30P are arrayed, the grounding member 110 may be disposed on the gap G formed between each display module 30A to 30P.

The grounding member 110 may be provided in a thin shape. This is because the grounding member 110 is disposed between the gap G formed between the display modules 30A to 30P when the display modules 30A to 30P are tiled. When the grounding member 110 has a relatively large thickness, the gap G formed between the display modules 30A to 30P may be formed large due to the thickness of the grounding member 110, and thus the seam between the display modules 30A to 30P may be perceived.

However, because the grounding member 110 is provided in a thin shape, the visibility of the seam may be minimized.

The grounding member 110 may be formed of a highly conductive material. For example, the grounding member 110 may be formed of metal, conductive polymer, conductive fabric, etc., and may be formed of a material that is electrically grounded to the metal plate 60.

The grounding member 110 may be formed of a material with higher conductivity than the front cover 70 and the anisotropic conductive layer 47. When an electric current is generated by ESD on the front cover 70 or the side cover 90, the electric current may not penetrate the front cover 70, the anisotropic conductive layer 47, and the side cover 90. Accordingly, the electric current may not flow into the substrate 40 but flow on the front cover 70 and then flow into the grounding member 110.

The electric current flowing into the grounding member 110 may flow to the metal plate 60 through the grounding member 110. This is because the grounding member 110 is provided to be in contact with the metal plate 60 and grounded to the ground configuration.

That is, the grounding member 110 may provide a path in which the electric current due to ESD generated on the front cover 70 or the side cover 90 flows to the metal plate 60 provided as a ground configuration. The grounding member 110 may guide charges caused by ESD to allow the charges to flow to the ground.

Accordingly, as most of the electric current due to ESD on the front cover 70 or the side cover 90 flows to the metal plate 60 through the highly conductive grounding member 110, ESD withstand voltage of the electrical components mounted on the substrate 40 may be improved even when some of the electric current flows toward the substrate 40.

The electrostatic current additionally transmitted to the metal plate 60 may be discharged to the external ground through components in contact with the metal plate 60, such as bridge boards and cables.

Hereinafter a display apparatus 1 including the side end cover 100 and the grounding member 110 according to some embodiments will be described.

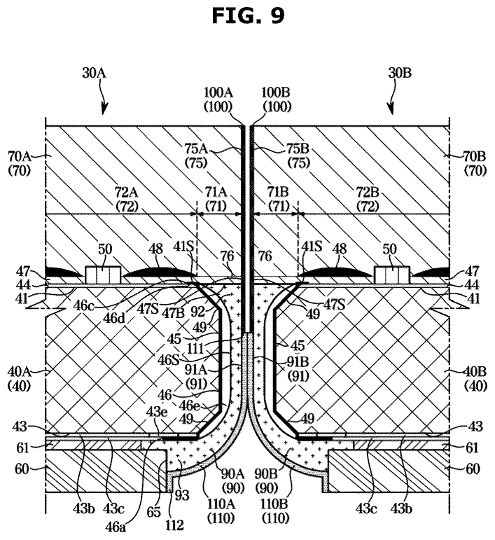

FIG. 9 is an enlarged cross-sectional view illustrating some components of a display apparatus according to some embodiments of the present disclosure.

For example, the display apparatus 1 may include both the side cover 100 and the grounding member 110 to ensure ESD reliability.

The side end cover 100 may be disposed in front of the grounding member 110 with respect to the first direction X.

The side end cover 100 may be provided to extend from a front end of the front cover 70 in the first direction X to at least a portion of the side cover 90 through the side end 47S of the anisotropic conductive layer 47. One end portion 111 of the grounding member 110 may be disposed below the side end member 100 in the first direction X, and the other end portion 112 of the grounding member 110 may be provided to be in contact with the metal plate 60.

Hereinafter a display apparatus 1 including a side cover 90 extending to the side end 75 of the front cover 70 according to some embodiments will be described.

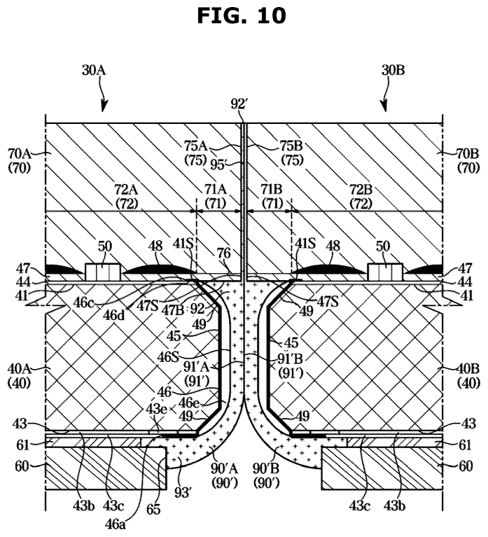

FIG. 10 is an enlarged cross-sectional view illustrating some components of a display apparatus according to some embodiments of the present disclosure.

For example, a side cover 90′ may be provided to cover not only the side surface 45 of the substrate 40 but also the side end 75 of the front cover 70.

The side cover 90′ may include a front portion 95′ covering the side end 75 of the front cover 70. The front portion 95′ may be provided to cover from the side end 75 of the front cover 70 to the side end 47S of the anisotropic conductive layer 47.

One end portion 92′ of the side cover 90′ in the first direction X may be provided to extend from the front end of the front cover 70. The other end portion 93′ of the side cover 90′ in the first direction X may be provided to be in contact with the side surface 65 of the metal plate 60.

The side cover 90′ may be provided to cover the entire edge of the front cover 70 and the substrate 40 of the display modules 30A to 30P.

Accordingly, when an electric current is generated on the side edge of the display modules 30A to 30P due to ESD, the electric current may not flow into the anisotropic conductive layer 47 but be guided to the metal plate 60 by the side cover 90′.

For example, the front portion 95′ of the side cover 90′ may be disposed at lateral-most ends of the first display module 30A and the second display module 30B, respectively. A side end 91′A of a side cover 90′A of the first display module 30A and a side end 91′B of a side cover 90′B of the second display module 30B may be arranged side by side. The side end 91′A of the side cover 90′A of the first display module 30A and the side end 91′B of the side cover 90′B of the second display module 30B may be arranged in contact with each other.

The side end 91′A of the side cover 90′A of the first display module 30A and the side end 91′B of the side cover 90′B of the second display module 30B may be defined as a side end of the front portion 95′ of the side cover 90′.

Accordingly, a distance between the lateral-most ends of the first display module 30A and the second display module 30B may be the same as a thickness of a front portion 95′ of the side cover 90′A of the first display module 30A and a front portion 95′ of the side cover 90′B of the second display module 30B.

When the front portion 95 of the side cover 90 is not provided, a grounding member grounded to the metal plate 60 may be additionally disposed at the lateral-most end of the display modules 30A to 30P so as to prevent an electric current due to ESD from flowing into the anisotropic conductive layer 47 as the anisotropic conductive layer 47 is exposed to the outside. The grounding member may be generally formed of metal and have a predetermined thickness or more. The grounding member may increase the distance between the lateral-most ends of the display modules 30A to 30P, thereby increasing the visibility of the seam between the display modules 30A to 30P.

However, as the front portion 95 of the side cover 90 covers the anisotropic conductive layer 47 from the outside, ESD immunity due to ESD may be improved even without the grounding member, and thus the grounding member may be not disposed at the lateral-most end of the display module 30A to 30P. Accordingly, the distance between the lateral-most ends of the display modules 30A to 30P may be minimized, thereby reducing the visibility of the seam between the lateral-most ends of the display modules 30A to 30P.

Hereinafter a display apparatus 1 including a side cover 90 extending to the side end 75 of the front cover 70 and a grounding member 110 according to some embodiments will be described.

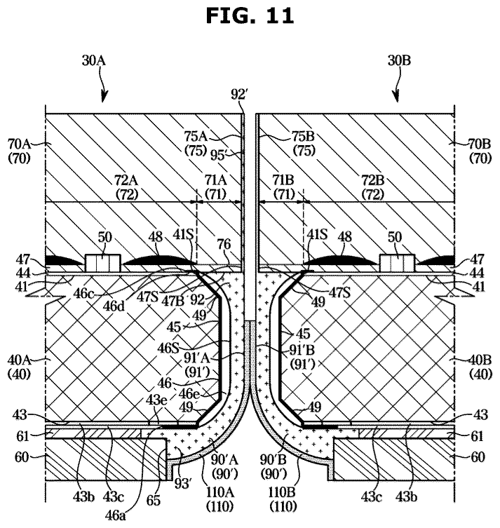

FIG. 11 is an enlarged cross-sectional view illustrating some components of a display apparatus according to some embodiments of the present disclosure.

For example, the display apparatus 1 may include both the side cover 90′ including the front portion 95′ and the grounding member 110 to ensure ESD reliability.

The front portion 95′ may be disposed in front of the grounding member 110 in the first direction X.

One end portion 111 of the grounding member 110 may be disposed below the front portion 95′ in the first direction X, and the other end portion 112 of the grounding member 110 may be provided to be in contact with the metal plate 60.

Although certain exemplary embodiments are illustrated and described above, the present disclosure is not limited to the certain embodiments, various applications may of course be performed by those skilled in the art without deviating from what is claimed in the scope of claims, and such applications should not be understood separately from the technical idea or prospects herein.

What is claimed is:

1. A display module comprising:
a substrate comprising:
a mounting surface having a thin-film transistor (TFT) layer formed thereon;
a side surface; and a
rear surface opposite to the mounting surface;
a plurality of inorganic light-emitting elements mounted on the mounting surface;
an anisotropic conductive layer on an upper surface of the TFT layer and configured to electrically connect the TFT layer to the plurality of inorganic light-emitting elements;
a front cover covering the mounting surface;
a side cover surrounding the side surface; and
a metal plate bonded to the rear surface,
wherein a side end of the front cover extends to a region outside the mounting surface, and
wherein the side cover is made of a moisture-proof material capable of preventing permeation of moisture, and extends to at least a portion of a side surface of the metal plate from a lower portion of the front cover corresponding to the region outside the mounting surface.

2. The display module of claim 1, wherein a side end of the anisotropic conductive layer extends to the region outside the mounting surface and corresponds to the side end of the front cover, and
wherein an upper surface of the side cover corresponding to the region outside the mounting surface contacts a lower surface of the anisotropic conductive layer corresponding to the region outside the mounting surface.

3. The display module of claim 1, further comprising:
a side end cover extending from at least a portion of the side end of the front cover to at least a portion of a side end of the side cover in a direction to which the mounting surface faces, and configured to cover a side end of the anisotropic conductive layer.

4. The display module of claim 3, wherein the side end cover is black.

5. The display module of claim 3, wherein the side end cover is made of a moisture-proof material capable of preventing permeation of moisture.

6. The display module of claim 3, wherein the side end cover extends from a front end of the front cover to an under-side of the side end of the anisotropic conductive layer in the direction to which the mounting surface faces.

7. The display module of claim 1, wherein the side cover is black.

8. The display module of claim 1, wherein the side cover is made of a water-repellent material.

9. The display module of claim 1, further comprising:
a grounding member covering at least a portion of a side end of the side cover and contacting the side surface of the metal plate.

10. The display module of claim 9, wherein the grounding member is made of metal.

11. The display module of claim 1, wherein the side cover extends from a front end of the side end of the front cover to the side surface of the metal plate in a direction to which the mounting surface faces.

12. A display apparatus comprising:
a display module array comprising a plurality of display modules horizontally arranged in an M*N matrix form; and
a frame configured to support the plurality of display modules,
wherein each of the plurality of display modules comprises:
a substrate comprising:
a mounting surface having a thin-film transistor (TFT) layer formed therein;
a side surface; and
a rear surface opposite to the mounting surface;
a plurality of inorganic light-emitting elements mounted on the mounting surface;
an anisotropic conductive layer on an upper surface of the TFT layer and configured to electrically connect the TFT layer to the plurality of inorganic light-emitting elements;
a front cover covering the mounting surface;
a side cover surrounding the side surface; and
a metal plate bonded to the rear surface,
wherein a side end of the front cover extends to a region outside the mounting surface, and
wherein the side cover is made of a moisture-proof material capable of preventing permeation of moisture, and extends to at least a portion of a side surface of the metal plate from a lower portion of the front cover corresponding to the region outside the mounting surface.

13. The display apparatus of claim 12, wherein
a side end of the anisotropic conductive layer extends to the region outside the mounting surface and corresponds to the side end of the front cover, and
wherein an upper surface of the side cover corresponding to the region outside the mounting surface contacts a lower surface of the anisotropic conductive layer corresponding to the region outside the mounting surface.

14. The display apparatus of claim 12, further comprising:
a side end cover extending from at least a portion of the side end of the front cover to at least a portion of a side end of the side cover in a direction to which the mounting surface faces, and configured to cover a side end of the anisotropic conductive layer.

15. The display apparatus of claim 14, wherein the side end cover is black.
